(19) United States
(12) Patent Application Publication
(10) Pub. No.: US 2024/0047374 A1
(43) Pub. Date: Feb. 8, 2024

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien Chiu, Taichung City (TW); Chih-Chiang He, Taichung City (TW); Chun-Chong Chien, Taichung City (TW); Wen-Jung Tsai, Taichung City (TW)

(73) Assignee: SILICONWARE PRECISION INDUSTRIES CO., LTD., (omitted)

(21) Appl. No.: 17/968,349

(22) Filed: Oct. 18, 2022

(30) Foreign Application Priority Data
Aug. 3, 2022 (TW) 111129167

(51) Int. Cl. H01L 23/552; H01L 23/31; H01L 21/56; H01L 23/00

(52) U.S. Cl. CPC H01L 23/552; H01L 23/3157; H01L 21/56; H01L 24/05; H01L 24/13; H01L 2924/3025; H01L 2224/0401; H01L 2224/13023; H01L 2924/1811

(57) ABSTRACT

An electronic package is provided with a plurality of electronic elements disposed on a carrier structure and a shielding structure located between two adjacent electronic elements, where the shielding structure is formed with at least one cavity and shielding members located on opposite sides of the cavity, such that the shielding members are arranged between the two electronic elements. Therefore, the electromagnetic signal will be reflected via the shielding members to prevent the two electronic elements from electromagnetically interfering with each other.

### BACKGROUND

### 1. Technical Field

The present disclosure relates to a semiconductor device, and more particularly, to an electronic package with a shielding structure and a manufacturing method thereof.

### 2. Description of Related Art

With the evolution of semiconductor technology, different package product types have been developed for semiconductor products, and in order to improve electrical quality, various semiconductor products have a shielding function to prevent electromagnetic interference (EMI).

As shown in FIG. 1A, in a conventional radio frequency (RF) module 1 for avoiding EMI, a plurality of semiconductor chips 11, a passive element 19 and a shielding member 12 are disposed on a package substrate 10, wherein the semiconductor chips 11 and the passive element 19 are electrically connected to the package substrate 10, and the shielding member 12 is located between two adjacent semiconductor chips 11. Next, a package colloid 13 is formed on the package substrate 10 to cover the semiconductor chips 11 and the shielding member 12. Afterwards, a metal layer 14 is formed on the package colloid 13 to protect the semiconductor chips 11 from being affected by the external EMI.

However, in the conventional radio frequency module 1, if the electromagnetic waves of the semiconductor chips 11 are too strong, and if only a single metal plate is used as the shielding member 12 between the two semiconductor chips 11, as shown in FIG. 1B, then electromagnetic interference (EMI) between the semiconductor chips 11 will be unavoidable, resulting in errors in the signal transmission of the semiconductor chips 11 easily.

Therefore, how to overcome the above-mentioned drawbacks of the prior art has become an urgent issue to be solved at present.

### SUMMARY

In view of the various deficiencies of the prior art, the present disclosure provides an electronic package, comprising: a carrier structure; a plurality of electronic elements disposed on and electrically connected to the carrier structure; and a shielding structure disposed on the carrier structure and located between any two of the plurality of electronic elements, wherein the shielding structure is formed with at least one cavity and a plurality of shielding members located on opposite sides of the at least one cavity, such that the plurality of shielding members are located between any two of the plurality of electronic elements.

The present disclosure also provides a method of manufacturing an electronic package, comprising: disposing a plurality of electronic elements on a carrier structure, wherein the plurality of electronic elements are electrically connected to the carrier structure; and disposing a shielding structure on the carrier structure, wherein the shielding structure is located between any two of the plurality of electronic elements, and wherein the shielding structure is formed with at least one cavity and a plurality of shielding members located on opposite sides of the at least one cavity, such that the plurality of shielding members are located between any two of the plurality of electronic elements.

In the aforementioned electronic package and the manufacturing method thereof, the shielding structure has a plurality of sections with different widths, such that the at least one cavity is formed on a wider one of the plurality of sections. For example, a width of the wider one of the plurality of sections is at most ten times greater than a width of a narrower one of the plurality of sections.

In the aforementioned electronic package and the manufacturing method thereof, a top surface of the shielding structure is shaped like an I-shape, a zigzag-like shape, or a Φ shape.

In the aforementioned electronic package and the manufacturing method thereof, a depth of the at least one cavity is less than or equal to a thickness of the shielding structure.

In the aforementioned electronic package and the manufacturing method thereof, a depth of the at least one cavity is ⅕ to ⅘ of a thickness of the shielding structure.

In the aforementioned electronic package and the manufacturing method thereof, further comprising forming a cladding layer on the carrier structure to cover the plurality of electronic elements and the shielding structure. For example, at least a part of surfaces of the shielding structure is exposed from the cladding layer. Further, the present disclosure also comprises forming a sheltering layer on the cladding layer.

In the aforementioned electronic package and the manufacturing method thereof, the at least one cavity is opened toward the carrier structure and/or the at least one cavity is formed on a top surface of the shielding structure.

As can be seen from the above, in the electronic package and the manufacturing method thereof of the present disclosure, multiple shielding members are formed between two adjacent electronic elements via the design of the shielding member, so that the electromagnetic signal of one of the electronic elements is reflected by the shielding members to be away from the other electronic element. Therefore, compared with the prior art, the electronic elements of the present disclosure do not interfere with each other electromagnetically, so that the reliability of the end product will be better.

### BRIEF DESCRIPTION OF THE DRAWINGS

FIG. 1A is a schematic cross-sectional view of a conventional radio frequency module.

FIG. 1B is a schematic partial perspective view of FIG. 1A.

FIG. 2A-1, FIG. 2B and FIG. 2C-1 are schematic cross-sectional views illustrating a manufacturing method of an electronic package according to the present disclosure.

FIG. 2A-2 is a schematic partial perspective view of FIG. 2A-1.

FIG. 2A-3 is a schematic front plan view of FIG. 2A-2.

FIG. 2C-2 is a schematic cross-sectional view of another aspect of FIG. 2C-1.

FIG. 2C-3 is a schematic perspective view of another aspect of FIG. 2C-1.

FIG. 2D is a schematic partial cross-sectional view of FIG. 2C-1.

FIG. 3A is a schematic perspective view of another embodiment of FIG. 2A-2.

FIG. 3B is a schematic cross-sectional view of another embodiment of FIG. 2C-1.

FIG. 4A is a schematic perspective view of another embodiment of FIG. 3A.

FIG. 4B is a schematic cross-sectional view of another embodiment of FIG. 3B.

FIG. 4C is a schematic perspective view of another embodiment of FIG. 2A-2.

FIG. 5A is a schematic cross-sectional view of another embodiment of FIG. 2C-1.

FIG. 5B is a schematic partial perspective view of FIG. 5A.

FIG. 6A is a schematic cross-sectional view of another embodiment of FIG. 2C-1.

FIG. 6B is a schematic partial perspective view of FIG. 6A.

FIG. 6C is a schematic perspective view of another aspect of FIG. 6B.

FIG. 7 is a schematic cross-sectional view of another aspect of FIG. 6B.

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “first,” “second,” “one,” “a,” “an” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

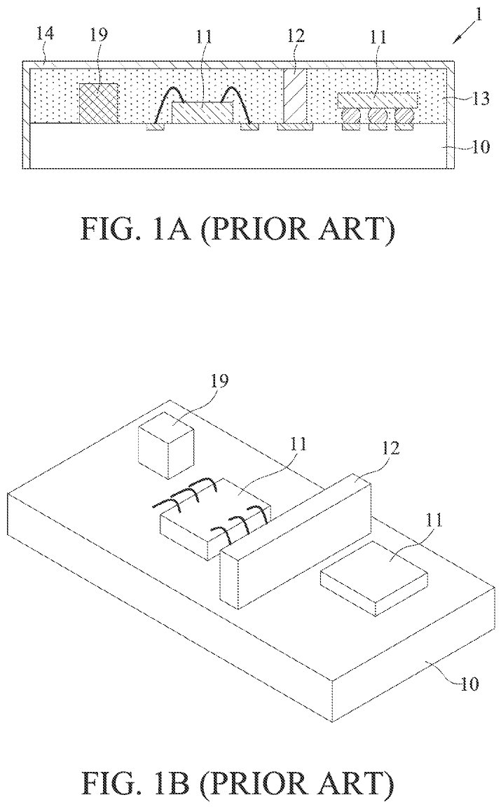

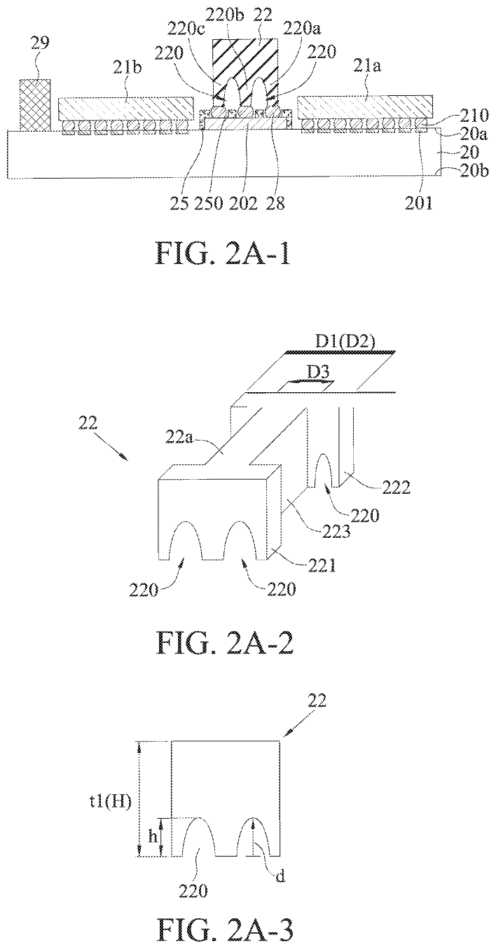

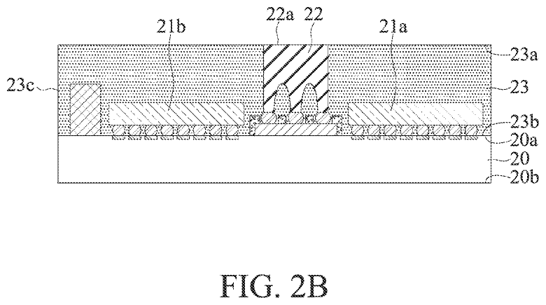

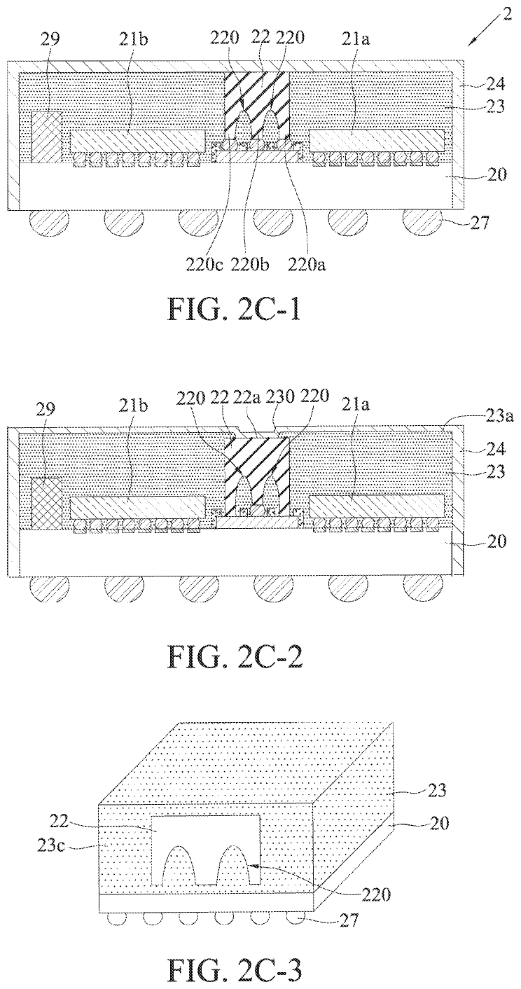

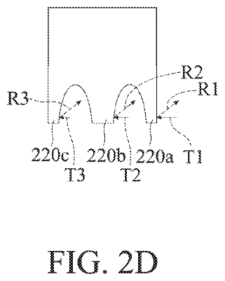

FIG. 2A-1, FIG. 2B and FIG. 2C-1 are schematic cross-sectional views illustrating a manufacturing method of an electronic package 2 according to the present disclosure.

As shown in FIG. 2A-1, a carrier structure 20 is provided, which has a first side 20a and a second side 20b opposite to each other, wherein a plurality of electronic elements 21a, 21b, 29 separated from each other are disposed on the first side 20a of the carrier structure 20, and a shielding structure 22 is disposed on the first side 20a of the carrier structure 20.

The carrier structure 20 is a circuit structure with a core layer or a coreless circuit structure. The carrier structure 20 has at least one dielectric layer and a circuit layer disposed on the dielectric layer, such as a fan-out type redistribution layer (RDL), and the outermost circuit layer has a plurality of electrical contact pads 201 and at least one external pad 202.

In an embodiment, the material for forming the circuit layer is copper, and the material for forming the dielectric layer is, for example, polybenzoxazole (PBO), polyimide (PI), prepreg (PP) and other dielectric materials.

It should be understood that the carrier structure 20 can also be other carriers for carrying chips, such as organic sheets, wafers, or other carriers with metal routing, but the present disclosure is not limited to as such.

Each of the electronic elements 21a, 21b, 29 is an active element, a passive element, or a combination of the active element and the passive element, where the active element is, for example, a semiconductor chip (such as the electronic element 21a and the electronic element 21b), and the passive element (such as the electronic element 29) is such as a resistor, a capacitor, or an inductor.

In an embodiment, the electronic elements 21a, 21b are radio frequency chips, such as Bluetooth chips or Wi-Fi chips, but may also be other electronic elements that are not interfered by electromagnetic waves. For example, the electronic elements 21a, 21b are disposed on the electrical contact pads 201 of the carrier structure 20 in a flip-chip manner via a plurality of conductive bumps 210 made of such as solder material to electrically connect the circuit layer; alternatively, the electronic elements 21a, 21b can be electrically connected to the electrical contact pads 201 by a plurality of bonding wires (not shown) in a wire bonding manner. However, the manner in which the electronic elements 21a, 21b are electrically connected to the circuit layer is not limited to the above.

The shielding structure 22 is located between the two electronic elements 21a, 21b, and at least one cavity 220 with an opening facing the carrier structure 20 is formed. In an embodiment, two cavities 220 are formed, so that the side walls on opposite sides of the cavities 220 serve as shielding members 220a, 220b, 220c, so that the shielding members 220a, 220b, 220c are designed in a recessed manner in the embodiment, for example, three shielding members 220a, 220b, 220c are formed, and a plurality of the shielding members 220a, 220b, 220c are located between the two electronic elements 21a, 21b.

Please refer to FIG. 2A-2. In an embodiment, the shielding structure 22 is a conductive strip body, which defines a wall-shaped main section 223 and a first section 221 and a second section 222 respectively adjacent to opposite ends of the main section 223, so that a plurality of the cavities 220 are formed on the first section 221 and the second section 222, and a bottom surface of the main section 223 is flush with end surfaces of the shielding members 220a, 220b, 220c. For example, a width D1 of the first section 221 is equal to a width D2 of the second section 222, and the width D1 of the first section 221 is greater than a width D3 of the main section 223 (i.e., D1=D2>D3), so that a top surface 22a of the shielding structure 22 is shaped like an I-shape or a dog bone. Preferably, the width D1 of the first section 221 is at most ten times greater than the width D3 of the main section 223 (i.e., D3<D1≤10D3), so as to facilitate the fabrication of the shielding structure 22.

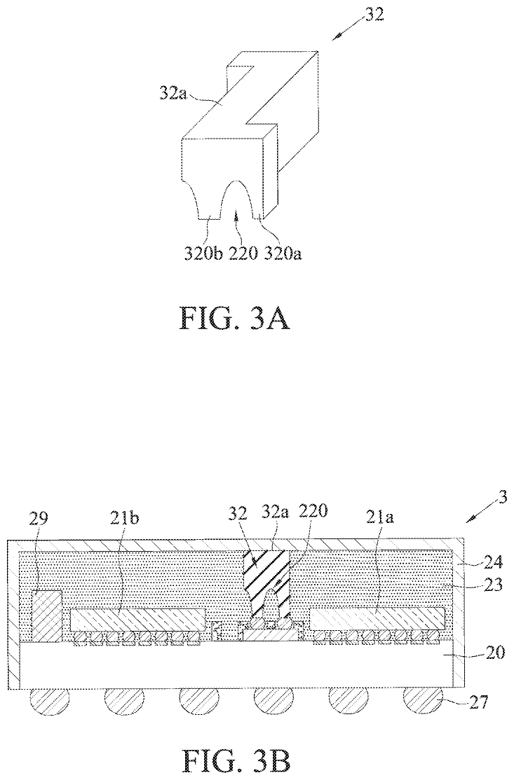

Further, a depth d of the cavity 220 is less than a thickness t1 of the shielding structure 22, as shown in FIG. 2A-3, that is, a height h of the cavity 220 relative to the first side 20a of the carrier structure 20 is less than a height H of the shielding structure 22 relative to the first side 20a of the carrier structure 20. For example, the depth d of the cavity 220 is ⅕ to ⅘ of the thickness t1 of the shielding structure 22 (i.e., d=t/5˜4t/5).

Furthermore, the cavity 220 is in the form of a channel, and the number of the cavity 220 on at least one section of the shielding structure 22 can be even or odd, so the number of the cavity 220 on the first section 221 or the second section 222 may be an even number (e.g., two); or, as shown in FIG. 3A and FIG. 3B, the number of the cavity 220 may be an odd number (e.g., one), so that a top surface 32a of a shielding structure 32 is shaped like a zigzag, and the number of the shielding members 320a, 320b is reduced to two.

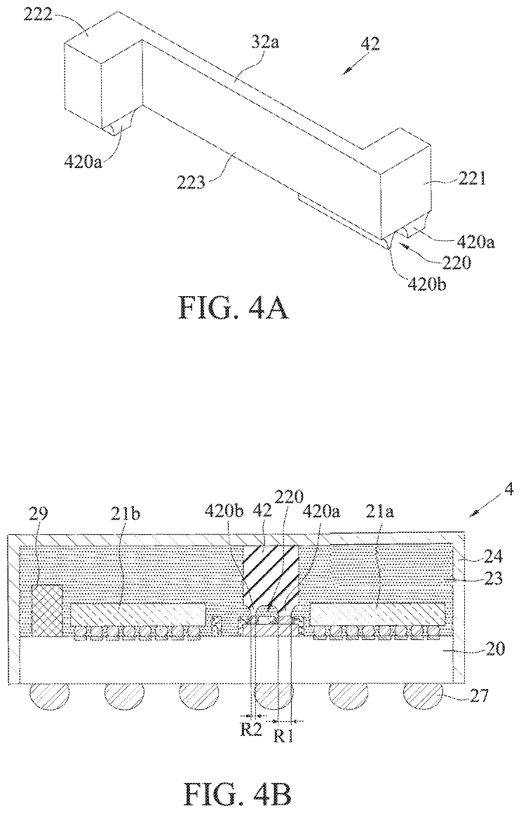

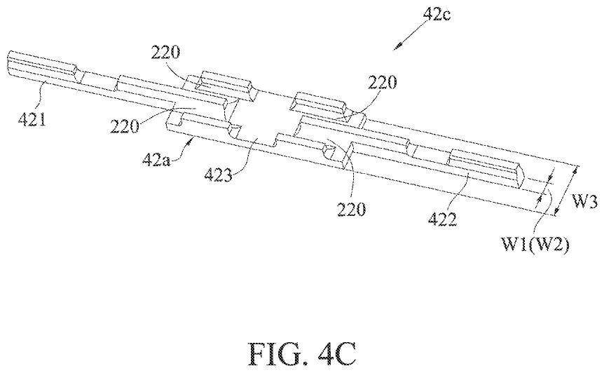

Also, the top surface 32a of the shielding structure 32 is in a zigzag-like shape. The shielding members 420a and 420b can be designed by an elevating manner, such as a shielding structure 42 shown in FIG. 4A and FIG. 4B, wherein two shielding members 420a, 420b with different widths R1, R2 are formed on the first section 221 and the second section 222 to serve as supporting feet, so that the main section 223 is suspended, and a cavity 220 is formed around the two shielding members 420a, 420b.

Therefore, there are many kinds of structures of the shielding structure 22, and the present disclosure is not limited to any particular kind, as long as the cavity 220 is provided. For example, in a shielding structure 42c shown in FIG. 4C, a width W1 of a first section 421 is equal to a width W2 of a second section 422, and the width W1 of the first section 421 is less than a width W3 of a main section 423, so that a top surface 42a of the shielding structure 42c is shaped like a and the position of the cavity 220 is located at the main section 423.

In addition, the shielding structure 22 can be bonded onto the external pad 202 of the carrier structure 20 via a conductive layer 28 such as solder material or conductive paste, so as to connect the carrier structure 20 to the ground. For example, the shielding members 220a, 220b, 220c are grounded and connected to the carrier structure 20 via the conductive layer 28; alternatively, the shielding structure 22 only has a partial shielding member 220b grounded and connected to the carrier structure 20 via the conductive layer 28, as shown in FIG. 2C-2, and the other shielding members 220a, 220c are only placed on the external pad 202 for support. Further, the first side 20a of the carrier structure 20 can be configured with an insulating protective layer 25 such as a solder resist, so that the insulating protective layer 25 forms a plurality of openings 250 exposing the external pad 202 for the conductive layer 28 to be located in the openings 250 to prevent the conductive layer 28 from overflowing into the cavity 220.

As shown in FIG. 2B, a cladding layer 23 is formed on the first side 20a of the carrier structure 20, so that the cladding layer 23 covers the electronic elements 21a, 21b, 29 and the shielding structure 22, wherein the cladding layer 23 has a first surface 23a and a second surface 23b opposite to each other and at least one side surface 23c adjacent to the first surface 23a and the second surface 23b, such that the shielding structure 22 is exposed from the first surface 23a of the cladding layer 23, and the cladding layer 23 is bonded onto the first side 20a of the carrier structure 20 with the second surface 23b thereof.

In an embodiment, the cladding layer 23 is made from an insulating material, such as polyimide (PI), dry film, package colloid such as epoxy resin, or molding compound. For example, the cladding layer 23 can be formed on the carrier structure 20 by liquid compound, injection, lamination, or compression molding, etc.

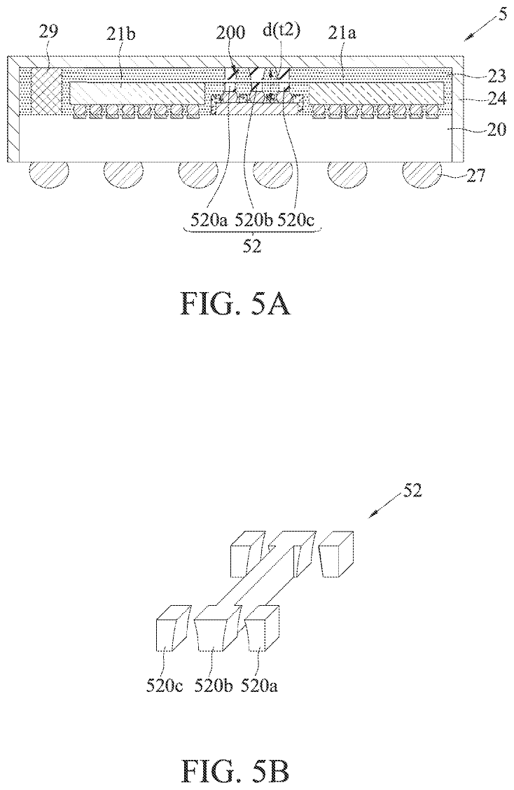

Furthermore, via a leveling process, the first surface 23a of the cladding layer 23 can be flush with the top surface 22a of the shielding structure 22, so that the top surface 22a of the shielding structure 22 is exposed from the first surface 23a of the cladding layer 23. For example, the leveling process removes partial materials of the cladding layer 23 by grinding, or even removes partial materials of the shielding structure 22 by grinding, so that the cavity 220 communicates with and is exposed from the first surface 23a of the cladding layer 23, such as a shielding structure 52 shown in FIG. 5A and FIG. 5B, so that the shielding members 520a, 520b, 520 are separated from each other, and the depth d of the cavity 220 is equal to a thickness t2 of the shielding structure 52.

Alternatively, partial materials of the first surface 23a of the cladding layer 23 may be removed by grinding or a laser method to form a recess 230 on the first surface 23a of the cladding layer 23, as shown in FIG. 2C-2, so that a part of the top surface 22a of the shielding structures 22 is exposed from the recess 230.

In addition, in other embodiments, the shielding structure 22 may also be exposed from the side surface 23c of the cladding layer 23. For example, the first section 221 (or the second section 222) and the cavity 220 thereof may be exposed from the side surface 23c of the cladding layer 23, as shown in FIG. 2C-3.

As shown in FIG. 2C-1, a sheltering layer 24 is formed on the first surface 23a of the cladding layer 23 by metal electroplating, so that the sheltering layer 24 contacts the top surface 22a of the shielding structure 22, such that the sheltering layer 24 is electrically connected to the shielding structure 22, and even the sheltering layer 24 can be extended onto the side surface 23c of the cladding layer 23 to form the electronic package 2 of the present disclosure. Afterwards, a plurality of conductive elements 27 such as solder balls can be formed on the second side 20b of the carrier structure 20 and electrically connected to the circuit layer of the carrier structure 20 so as to subsequently connect to an electronic device (not shown) such as a package structure, a chip, or a circuit board, etc.

In an embodiment, the sheltering layer 24 is formed of materials such as gold (Au), silver (Ag), copper (Cu), nickel (Ni), iron (Fe), aluminum (Al), stainless steel (SUS), and the like.

Furthermore, the sheltering layer 24 can also be formed by coating, sputtering, chemical plating, electroless plating, or vapor deposition. Alternatively, the sheltering layer 24 can be a metal cover plate or a conductive film to be attached onto the first surface 23a of the cladding layer 23.

Furthermore, if a part of the top surface 22a of the shielding structures 22 is exposed from the recess 230, as shown in FIG. 2C-2, the sheltering layer 24 will extend into the recess 230 to contact the top surface 22a of the shielding structure 22. Alternatively, if the shielding structure 22 is exposed from the side surface 23c of the cladding layer 23, as shown in FIG. 2C-3, the sheltering layer 24 contacts the first section 221 (or the second section 222) of the shielding structure 22.

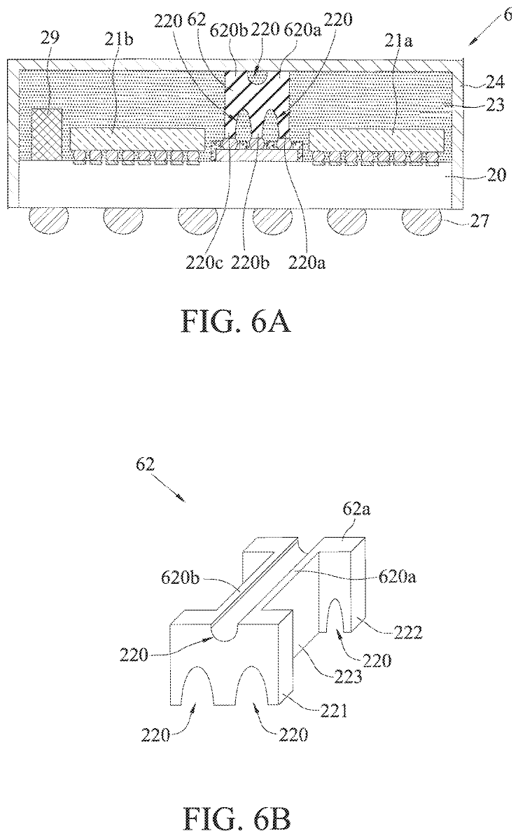

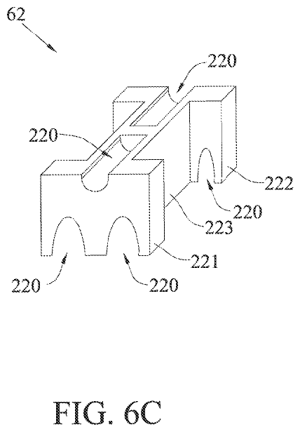

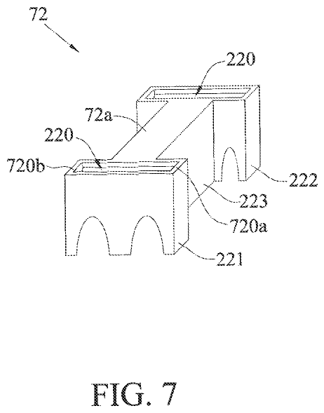

In addition, as shown in FIG. 6A, the cavity 220 can also be formed on a top surface 62a of a shielding structure 62, such as one shown in FIG. 6B or two shown in FIG. 6C or even more, wherein the cavity 220 extends from the first section 221 (and/or the second section 222) to the main section 223 to form shielding members 620a, 620b across the first section 221 (and/or the second section 222) and the main section 223. It can be understood that the cavity 220 on a top surface 72a of a shielding structure 72 can also be formed at the first section 221 (and/or the second section 222) only without extending to the main section 223 (as shown in FIG. 7), so that shielding members 720a, 720b are formed on the first section 221 (and/or the second section 222).

Therefore, the surrounding of the electronic elements 21a, 21b, 29 is covered with the shielding structure 22, 32, 42, 42c, 52, 62, 72 and the sheltering layer 24, so that when the electronic package 2 is in operation, the electronic elements 21a, 21b, 29 will not be subjected to electromagnetic interference (EMI) from the outside, and the electronic elements 21a, 21b will not electromagnetically interfere with each other, so the electrical operation function of the electronic package 2 will be normal, and thus the overall electrical performance of the electronic package 2 will not be affected.

Further, the electronic package 2, 3, 4, 5, 6 of the present disclosure forms a plurality of shielding members 220a, 220b, 220c, 320a, 320b, 420a, 420b, 520a, 520b, 520c, 620a, 620b, 720a, 720b spaced apart from each other between the two adjacent electronic elements 21a, 21b by the design of the cavity 220, so that the electromagnetic signal of one electronic element 21a is reflected (e.g., electromagnetic wave directions R1, R2, R3 as shown in FIG. 2D) by the shielding members 220a, 220b, 220c, 320a, 320b, 420a, 420b, 520a, 520b, 520c, 620a, 620b, 720a, 720b to be away from the other electronic element 21b (or the passive element such as the electronic element 29), even is buffered and weakened (e.g., electromagnetic wave intensities T1, T2, T3 as shown in FIG. 2D) by the shielding members 220a, 220b, 220c, 320a, 320b, 420a, 420b, 520a, 520b, 520c, 620a, 620b, 720a, 720b. Therefore, compared with the prior art, the electronic elements 21a, 21b of the present disclosure do not electromagnetically interfere with each other, so that the reliability of the end product will be better.

Preferably, the cavity 220 is located at a place where the interference signal is strong, for example, the first section 221 and the second section 222 where the width D1 and the width D2 of the shielding structure 22 are wider; or, the main section 423 where the width D3 of the shielding structure 42c is wider.

The present disclosure also provides an electronic package 2, 3, 4, 5, 6, comprising: a carrier structure 20, a plurality of electronic elements 21a, 21b and a shielding structure 22, 32, 42, 42c, 52, 62, 72.

The electronic elements 21a, 21b are disposed on the carrier structure 20 and are electrically connected to the carrier structure 20.

The shielding structure 22, 32, 42, 42c, 52 is disposed on the carrier structure 20 and located between any two of the plurality of electronic elements 21a, 21b, wherein the shielding structure 22, 32, 42c, 52 is formed with at least one cavity 220 and shielding members 220a, 220b, 220c, 320a, 320b, 420a, 420b, 520a, 520b, 520c, 620a, 620b, 720a, 720b located on opposite sides of the cavity 220, so that a plurality of the shielding members 220a, 220b, 220c, 320a, 320b, 420a, 420b, 520a, 520b, 520c, 620a, 620b, 720a, 720b are located between any two of the plurality of electronic elements 21a, 21b.

In one embodiment, the shielding structure 22, 42c has a first section 221, 421, a second section 222, 422 and a main section 223, 423 with different widths D1, D2, D3, W1, W2, W3, so that the cavity 220 is formed on the first section 221 and the second section 222 with wider widths D1 and D2; alternatively, the cavity 220 is formed on the main section 423 having a wider width W3. For example, the width D1 of the first section 221 is at most ten times greater than the width D3 of the main section 223.

In one embodiment, the top surface 22a, 32a, 42a, 62a, 72a of the shielding structure 22, 32, 42, 42c, 62, 72 is shaped like an I-shape, a zigzag-like shape, or a shape.

In one embodiment, the depth d of the cavity 220 is less than or equal to the thickness t1, t2 of the shielding structure 22, 52.

In one embodiment, the depth d of the cavity 220 is ⅕ to ⅘ of the thickness t1 of the shielding structure 22.

In one embodiment, the electronic package 2, 3, 4, 5, 6 further includes a cladding layer 23 formed on the carrier structure 20 to cover the plurality of electronic elements 21a, 21b and the shielding structure 22, 32, 42, 42c, 52, 62. For example, at least a part of the surfaces of the shielding structure 22, 32, 42, 42c, 52, 62, 72 (e.g., the top surface 22a, 32a, 42a, 62a, 72a and/or the surface at the cavity 220) is exposed from the cladding layer 23.

In one embodiment, the cavity 220 is opened toward the carrier structure 20 and/or the cavity 220 is formed on the top surface 62a, 72a of the shielding structure 62, 72.

To sum up, the electronic package of the present disclosure and the manufacturing method thereof are designed to form multiple shielding members between two adjacent electronic elements by the design of the shielding member, so that electromagnetic signals are reflected by the shielding members, such that the two adjacent electronic elements are not electromagnetically interfered with each other, and thus the electronic package of the present disclosure can effectively improve the reliability of the end product.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure;
a plurality of electronic elements disposed on and electrically connected to the carrier structure; and
a shielding structure disposed on the carrier structure and located between any two of the plurality of electronic elements, wherein the shielding structure is formed with at least one cavity and a plurality of shielding members located on opposite sides of the at least one cavity, such that the plurality of shielding members are located between any two of the plurality of electronic elements.

2. The electronic package of claim 1, wherein the shielding structure has a plurality of sections with different widths, such that the at least one cavity is formed on a wider one of the plurality of sections.

3. The electronic package of claim 2, wherein a width of the wider one of the plurality of sections is at most ten times greater than a width of a narrower one of the plurality of sections.

4. The electronic package of claim 1, wherein a top surface of the shielding structure is shaped like an I-shape, a zigzag-like shape, or a Φ shape.

5. The electronic package of claim 1, wherein a depth of the at least one cavity is less than or equal to a thickness of the shielding structure.

6. The electronic package of claim 1, wherein a depth of the at least one cavity is ⅕ to ⅘ of a thickness of the shielding structure.

7. The electronic package of claim 1, further comprising a cladding layer formed on the carrier structure to cover the plurality of electronic elements and the shielding structure.

8. The electronic package of claim 7, wherein at least a part of surfaces of the shielding structure is exposed from the cladding layer.

9. The electronic package of claim 7, further comprising a sheltering layer formed on the cladding layer.

10. The electronic package of claim 1, wherein the at least one cavity is opened toward the carrier structure and/or the at least one cavity is formed on a top surface of the shielding structure.

11. A method of manufacturing an electronic package, comprising:
disposing a plurality of electronic elements on a carrier structure, wherein the plurality of electronic elements are electrically connected to the carrier structure; and
disposing a shielding structure on the carrier structure, wherein the shielding structure is located between any two of the plurality of electronic elements, and wherein the shielding structure is formed with at least one cavity and a plurality of shielding members located on opposite sides of the at least one cavity, such that the plurality of shielding members are located between any two of the plurality of electronic elements.

12. The method of claim 11, wherein the shielding structure has a plurality of sections with different widths, such that the at least one cavity is formed on a wider one of the plurality of sections.

13. The method of claim 12, wherein a width of the wider one of the plurality of sections is at most ten times greater than a width of a narrower one of the plurality of sections.

14. The method of claim 11, wherein a top surface of the shielding structure is shaped like an I-shape, a zigzag-like shape, or a Φ shape.

15. The method of claim 11, wherein a depth of the at least one cavity is less than or equal to a thickness of the shielding structure.

16. The method of claim 11, wherein a depth of the at least one cavity is ⅕ to ⅘ of a thickness of the shielding structure.

17. The method of claim 11, further comprising forming a cladding layer on the carrier structure to cover the plurality of electronic elements and the shielding structure.

18. The method of claim 17, wherein at least a part of surfaces of the shielding structure is exposed from the cladding layer.

19. The method of claim 17, further comprising forming a sheltering layer on the cladding layer.

20. The method of claim 11, wherein the at least one cavity is opened toward the carrier structure and/or the at least one cavity is formed on a top surface of the shielding structure.
